(19) United States
(12) Patent Application Publication
(10) Pub. No.: US 2022/0208628 A1
(43) Pub. Date: Jun. 30, 2022

(54) CHIP PACKAGING STRUCTURE

(71) Applicant: Richtek Technology Corporation, Zhubei City (TW)

(72) Inventors: Shih-Chieh Lin, Kaohsiung (TW); Yong-Zhong Hu, Hsinchu (TW); Heng-Chi Huang, Hsinchu (TW); Hao-Lin Yen, Taoyuan (TW)

(21) Appl. No.: 17/565,402

(22) Filed: Dec. 29, 2021

Related U.S. Application Data
(60) Provisional application No. 63/132,410, filed on Dec. 30, 2020.

(30) Foreign Application Priority Data
Apr. 27, 2021 (TW) 110115026

(51) Int. Cl. H01L 23/31; H01L 23/15; H01L 23/495; H01L 23/367

(52) U.S. Cl. CPC H01L 23/3114; H01L 23/367; H01L 23/49513; H01L 23/15

(57) ABSTRACT

A chip packaging structure includes: at least one semiconductor chip, having a signal processing function; a base material, wherein the semiconductor chip is disposed on the base material; at least one thermal conduction plate, disposed on the base material; and a package material, encapsulating the base material, the thermal conduction plate, and the semiconductor chip. The thermal conduction plate forms at least one thermal conduction channel in the package material.

CROSS REFERENCE

The present invention claims priority to U.S. provisional application number 63/132410 filed on Dec. 30, 2020, and TW patent application number 110115026 filed on Apr. 27, 2021.

### BACKGROUND OF THE INVENTION

### Field of Invention

The present invention provides a chip packaging structure, in particular a chip packaging structure with thermal conduction plate and/or copper pillar attached to the base material to increase the heat transfer effect thereof.

### Description of Related Art

FIG. 1 shows a prior art chip packaging structure according to Korean Patent No. KR 101271374, wherein the base material 11 is made of a silicon material. For heat dissipation purpose, many grooves 22 are provided on the base material 11 to increase the heat dissipation surface area. For these grooves, the manufacturing process needs an additional photomask and lithography and etching steps, which increase the complexity of the manufacturing process. In addition, the heat can easily accumulate within the grooves 22, so the actual heat dissipation effect is not satisfactory.

FIG. 2 shows a chip packaging structure according to U.S. Pat. No. 8,202,765. In FIG. 2, the chip CH is connected to an outer cover 210 via a thermal conduction material 220, so that the heat generated by the chip CH can be transferred to the outside of the chip packaging structure through the thermal conduction material 220 and the outer cover 210. However, this design has several shortcomings: 1. The space between the outer cover 220 and the chip can accumulate a lot of heat, causing the chip temperature to rise. 2. The outer cover 220 is made by a specific technology, so the size of this outer cover 220 can only be used in larger scale chip packages but not suitable for smaller scale chip packages.

In view of the above, the present invention provides a chip packaging technology with high heat dissipation efficiency. This technology has the benefits of easy and simple manufacturing process, low cost, and no package size limitation.

### SUMMARY OF THE INVENTION

For achieving high heat dissipation efficiency, in one perspective, the present invention provides a chip packaging structure, including: at least one semiconductor chip, having a signal processing function; abasematerial, the semiconductor chip being disposed on the base material; at least one thermal conduction plate, disposed on the base material; and a package material, encapsulating the base material, the thermal conduction plate and/or the at least one semiconductor chip; wherein the thermal conduction plate forms at least one thermal conduction channel.

In the prior art, the heat generated by the semiconductor chip is transferred to the outside of the chip packaging structure via the base material and the package material, and the heat transfer effect is often insufficient in this way. In the present invention, the copper pillar or thermal conduction plate, which does not provide signal processing or transmission function, is attached to the base material to establish a thermal conduction channel through the copper pillar or the thermal conduction plate, whereby the heat dissipation efficiency of the chip packaging structure can be greatly increased.

In one embodiment, a structure of the base material includes a lead frame or a substrate.

In one embodiment, the chip packaging structure further includes at least one copper pillar disposed on the base material, wherein the copper pillar is encapsulated by the package material to form at least one thermal conduction channel inside the package material. The copper pillar does not have a signal transmission function, and the heat transfer coefficient of the copper pillar is higher than that of the package material.

In one embodiment, the chip packaging structure can be used in flip chip package, land grid array package (LGA) , or die exposed package.

In one embodiment, the package material includes a molding compound or a ceramic material.

In one embodiment, viewing along the normal direction of the base material, the projection areas of the thermal conduction plate and the semiconductor chip can overlap. Or, in another embodiment, the projection areas of the thermal conduction plate and the semiconductor chip do not overlap with each other.

In addition, in the chip packaging structure of the present invention, there can be two or more thermal conduction plates, wherein at least two of the thermal conduction plates can be connected to each other by wire bonding, to increase the heat transfer effect.

In one embodiment, the semiconductor chip includes plural pads, wherein the pads include signal transmission pads and non-signal transmission pads. The copper pillar can be connected to one or more of the signal transmission pads and/or the non-signal transmission pads.

In one embodiment, when the thickness of the thermal conduction plate is thicker, the heat dissipation effect of the thermal conduction plate is higher.

In one embodiment, at least one of the thermal conduction plate and the copper pillar can be connected to each other, by wire bonding or by at least one pad of the semiconductor chip.

In one embodiment, the semiconductor chip includes an circuit which generates heat during operation, such as a processor or an active component.

In one embodiment, the chip packaging structure of the present invention can be used in land grid array packages (LGA), lead frame packages, flip chip packages, and die exposed packages.

In one embodiment, the copper pillar is connected to a grounding pad.

In one embodiment, at least one top surface of the thermal conduction plate is exposed to the outside of the package material.

In one embodiment, the chip packaging structure includes plural thermal conduction plates, which substantially have the same height level.

The objectives, technical details, features, and effects of the present invention will be better understood with regard to the detailed description of the embodiments below, with reference to the attached drawings.

### BRIEF DESCRIPTION OF THE DRAWINGS

FIGS. 1 and 2 show schematic diagrams of chip packaging structures according to prior arts.

FIGS. 3A, 3B, 4 and 5 show schematic diagrams of chip packaging structures according to several embodiments of the present invention.

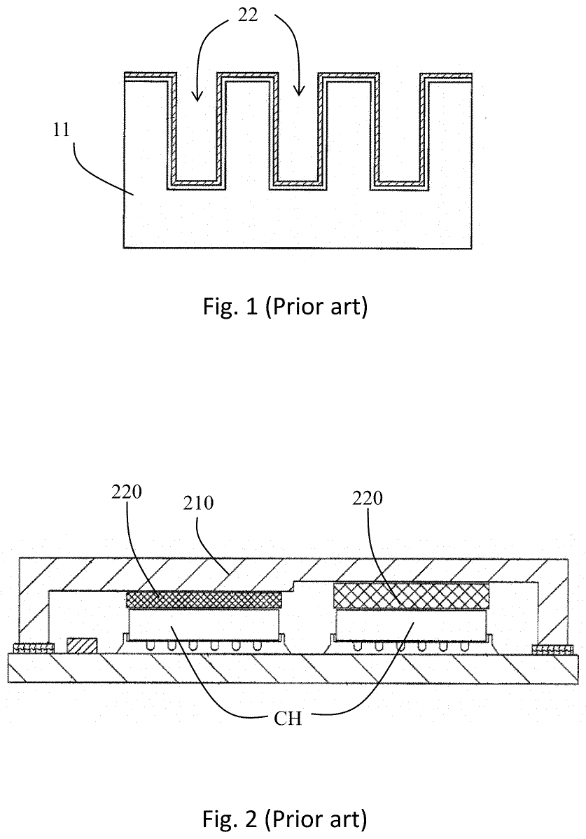

### DESCRIPTION OF THE PREFERRED EMBODIMENTS

The drawings as referred to throughout the description of the present invention are for illustration only, to show the interrelations between the components or units, but not drawn according to actual scale of sizes.

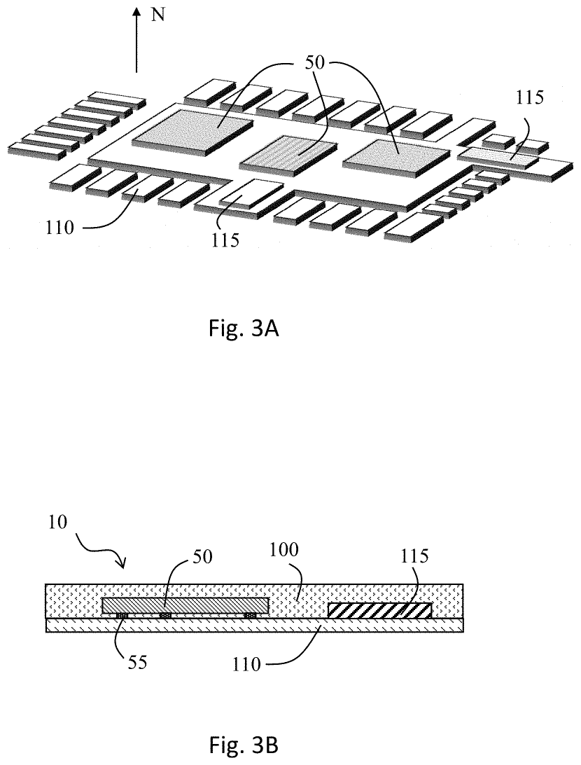

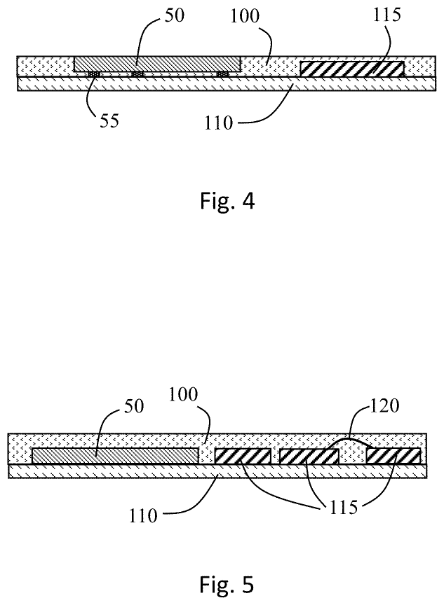

Please refer to FIGS. 3A and 3B, wherein FIG. 3A is a schematic view showing a status before packaging, and FIG. 3B is a schematic view showing to a status after packaged by a package material. The present invention provides a chip packaging structure 10, which includes: at least one semiconductor chip 50, a base material 110, and a package material 100. The at least one semiconductor chip 50 has a signal processing function, wherein optionally, the at least one semiconductor chip 50 includes at least one copper pillar 55. (three copper pillars 55 are shown in the figure as an example; however, the number of copper pillars 55 is not limited to this number, and can be determined according to heat dissipation or other requirements; for example, there can be no copper pillar, or any number of copper pillars). The semiconductor chip 50 is disposed on the base material 110, wherein one end of each of the copper pillars 55 is in contact with the base material 110 for thermal conduction from the semiconductor chip 50, or in another embodiment, at least one thermal conduction plate 115 is disposed on the base material 110 (two thermal conduction plates 115 are shown in the figure as an example; however, the number of thermal conduction plates 115 is not limited to this number, and can be determined according to heat dissipation or other requirements; for example, there can be no thermal conduction plates 115, or any number of thermal conduction plates 115). The package material 100 encapsulates the base material 110, the semiconductor chip 50, and the copper pillar 55 and/or the thermal conduction plate 115. In one embodiment, the package material 100 encapsulates a top surface of the semiconductor chip 50 (FIGS. 3B and 5), while in another embodiment, the package material 100 does not encapsulate the top surface of the semiconductor chip 50 (FIG. 4)). The heat transfer coefficients of the thermal conduction plate 115 and the copper pillar 55 are higher than the package material (for example, 1 to 4 W/(mK)). The thermal conduction plate 115 is made of a silicon-based material (having a heat transfer coefficient of about 117 W/(mK)) or a copper-based material (having a heat transfer coefficient of about 385 W/(mK)) . In the chip packaging structure 10, the thermal conduction plate (s) 115 and/or the copper pillar (s) 50 form at least one thermal conduction channel within the package material 100 due to their high heat transfer coefficients.

In the prior art, the space on the base material 110 other than those of the semiconductor chip 50 and signal interconnection contacts is covered by the package material 100. The present invention makes use of the vacant space on the base material 110, by arranging at least one thermal conduction plate 115 and/or copper pillar 55 in such space to increase the heat dissipation of the chip packaging structure 10, wherein the thermal conduction plate 115 and/or copper pillar 55 does not provide a signal processing or transmission function. In the prior art which uses a normal package material, the heat dissipation effect is ordinary and sometimes even insufficient, so the prior art often uses other active heat dissipation components to increase the heat dissipation, but such active heat dissipation components usually consume a lot of power and occupy space, which is inferior to the present invention. In one embodiment of the present invention, instead of using a molding compound as the package material 100, the package material 100 can use a ceramic material.

In one embodiment, the semiconductor chip 50 is a device generating heat during operation, which for example includes a processor circuit or active components. When the semiconductor chip 50 generates a large amount of heat, the thermal conduction channels provided by the present invention can greatly increase the heat dissipation efficiency of the chip packaging structure 10.

In one embodiment, one of the copper pillar 55 and the thermal conduction plate 115 is incorporated in the chip packaging structure 10. Or, in another embodiment, both of the copper pillar 55 and the thermal conduction plate 115 are incorporated in the chip packaging structure 10.

In one embodiment, the copper pillar 55 can be, for example, a copper pillar structure used in disposing solder balls on the semiconductor chip 50. Solder ball mounting packaging technology is well known, and the present invention makes use of such copper pillar to enhance the heat dissipation effect of the chip packaging structure 10, so that no additional manufacturing process is required while the heat dissipation effect is enhanced.

In one embodiment, in addition to positioning the semiconductor chip 50, the base material 110 also provides signal connections to the semiconductor chip 50; the base material can include a lead frame or a substrate.

In one embodiment, the chip packaging structure of the present invention can be applied in flip chip package, land grid array (LGA), or die exposed package, etc. FIG. 4 shows an example of the present invention applied in the die exposed chip package, wherein the top surface of the chip 50 is exposed to the outside the package material 100.

In one embodiment, viewing along the normal direction of the base material, the projection areas of at least one thermal conduction plate and at least one semiconductor chip overlap with each other. Or, in another embodiment, the projection areas of the thermal conduction plate and the semiconductor chip do not overlap with each other. For example, as shown in FIG. 3A, the thermal conduction plate 115 and the semiconductor chip 50 can be separately disposed on the base material 110. Viewing along the normal direction N of the base material 110, the projection areas of the thermal conduction plate 115 and the semiconductor chip 50 do not overlap each other. In one embodiment, if preferred, the thermal conduction plates 115 can be arranged on two opposite sides of the base material 110; under such circumstance, in one embodiment, in the normal direction N of the base material 110, a portion of the projection areas of the thermal conduction plates 115 can overlap with the projection area of the semiconductor chip 50.

In another perspective, the heat transfer coefficient of the thermal conduction plate and the copper pillar is much higher than that of the package material, so that the thermal conduction plate and the package material can form thermal conduction channels via different materials. In a macro view, the thermal conduction plate raises the overall heat transfer coefficient of the chip packaging structure, such that it increases the overall heat transfer efficiency.

In one embodiment, in the chip packaging structure 10 including multiple thermal conduction plate 115, to further increase the heat transfer effect, at least a portion of the thermal conduction plates 115 (for example, two or more of the thermal conduction plates 115) can be connected to each other by wire bonding. As shown in FIG. 5, the thermal conduction plates 115 can be connected by a wire 120 in between, preferably a wire 120 with a high heat transfer coefficient.

In one embodiment, the semiconductor chip 50 includes plural pads. There are several options for the materials of the pads, such as aluminum pads or copper pads, requiring different manufacturing processes. According to the present invention, in one embodiment, the pads in the semiconductor chip 50 include at least one signal transmission pad and at least one non-signal transmission pad. The signal transmission pad can be utilized to send and receive signals. The non-signal transmission pad does not have the signal transmission function. The copper pillars can be connected to one or more of the signal transmission pad and/or the non-signal transmission pad.

In one embodiment, the thermal resistance of the chip packaging structure 10 is inversely correlated to the thickness of the thermal conduction plate 115, wherein the thermal resistance is a parameter which is defined as:

R=ΔT/P,

wherein ΔT is the temperature difference, and P is the heat consumption of the chip. The thermal resistance R represents how strong the material resists a heat flow through it (i.e., reciprocal of thermal conductance) . When the thermal resistance is higher, the heat dissipation performance is lower. When the thermal resistance is lower, the heat dissipation performance is higher. In other words, the thicker the thermal conduction plate 115 is, the higher the heat dissipation performance becomes. When the thickness of the thermal conduction plate 115 in the chip packaging structure 10 is thicker, the heat dissipates faster and the temperature of the semiconductor chip 50 after a unit time is lower. Thus, the heat dissipation performance of the chip packaging structure 10 for the semiconductor chip 50 can be designed by determining the number and thickness of the thermal conduction plates 115.

In one embodiment, the at least one thermal conduction plate and copper pillar can be connected to each other, via at least one pad of the semiconductor chip or by wire bonding, to increase the heat dissipation performance.

In one embodiment, the semiconductor chip 50 is mounted on the base material 110 by flip chip technology, and at least one copper pillar 55 is provided for increasing the heat dissipation performance for the semiconductor chip 50. In one embodiment, the at least one copper pillar 55 is connected to a grounding pad, wherein the grounding pad is electrically connected to the ground. In one embodiment, the chip packaging structure 10 includes plural thermal conduction plates 115, and the plural thermal conduction plates 115 substantially have the same height level.

In one embodiment, at least one of the top surfaces of the thermal conduction plates 155 is exposed to the outside of the package material 100. That is, in such embodiment, the package material 100 does not completely encapsulate the thermal conduction plate 155, such that at least one of the top surfaces of the thermal conduction plates 155 is exposed.

In short, the present invention can increase the heat dissipation performance of the chip packaging structure by employing the copper pillar or the thermal conduction plate, with a simple structure and a simple manufacturing process. Importantly, the present invention does not increase the size of the chip packaging structure, nor limit the package size of the chip packaging structure, while it increases the heat dissipation effect of the chip packaging structure.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A chip packaging structure, including:
at least one semiconductor chip, having a signal processing function;
a base material, the semiconductor chip being disposed on the base material;
at least one thermal conduction plate, disposed on the base material; and
a package material, encapsulating the base material, the thermal conduction plate and/or the at least one semiconductor chip;
wherein the thermal conduction plate forms at least one thermal conduction channel.

2. The chip packaging structure according to claim 1, wherein a structure of the base material includes a lead frame or a substrate.

3. The chip packaging structure according to claim 1, further including at least one copper pillar, which is disposed on the base material and encapsulated by the package material to form at least another thermal conduction channel, wherein the copper pillar does not have a signal transmission function, and the heat transfer coefficient of the copper pillar is higher than that of the package material.

4. The chip packaging structure according to claim 1, wherein the chip packaging structure is used in flip chip package, land grid array package (LGA), or die exposed chip package.

5. The chip packaging structure according to claim 1, wherein the package material includes a molding compound or a ceramic material.

6. The chip packaging structure according to claim 1, wherein a heat transfer coefficient of the thermal conduction plate is higher than that of the package material.

7. The chip packaging structure according to claim 1, wherein the thermal conduction plate is made of a silicon-based material or a copper-based material.

8. The chip packaging structure according to claim 1, wherein along a normal direction of the base material, a projection area of the at least one thermal conduction plate and a projection area of the at least one semiconductor chip do not overlap each other.

9. The chip packaging structure according to claim 1, wherein the at least one thermal conduction plate includes plural thermal conduction plates, wherein at least two of the thermal conduction plates are connected to each other by wire bonding.

10. The chip packaging structure according to claim 3, wherein the semiconductor chip further includes at least one signal transmission pad and at least one non-signal transmission pad, wherein the copper pillar is connected to the signal transmission pad and/or the non-signal transmission pad.

11. The chip packaging structure according to claim 1, wherein a thermal resistance of the chip packaging structure is inversely correlated to a thickness of the thermal conduction plate.

12. The chip packaging structure according to claim 3, wherein the at least one thermal conduction plate and the copper pillar are connected to one another by wire bonding or by at least one pad of the semiconductor chip.

13. The chip packaging structure according to claim 3, wherein the copper pillar is connected to a grounding pad.

14. The chip packaging structure according to claim 1, wherein at least one top surface of the at least one thermal conduction plate is exposed to the outside of the package material.

15. The chip packaging structure according to claim 1, wherein the at least one thermal conduction plate includes plural thermal conduction plates, and the plural thermal conduction plates substantially have the same height level.
